(19) United States
(12) Patent Application Publication
(10) Pub. No.: US 2015/0001277 A1
(43) Pub. Date: Jan. 1, 2015

(54) MULTI-SPOT SOLDERING APPARATUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: TAO ZHAO, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/011,728

(22) Filed: Aug. 27, 2013

(30) Foreign Application Priority Data
Jun. 28, 2013 (CN) 2013102643415

(51) Int. Cl. B23K 3/06

(52) U.S. Cl. CPC B23K 3/0646; H05K 13/04
USPC 228/39

(57) ABSTRACT

A multi-spot soldering apparatus which applies temperature protection to molten solder to be applied to the contacts of electronic components on printed circuit boards is provided. The multi-spot soldering apparatus includes a bottom plate, a number of containers mounted on the bottom plate and communicating with the multiple solder pot, and a number of protrusions mounted on the containers. Each of the protrusions defines an opening communicating with a container and the size and shape of each protrusion reduces the exposure of molten solder to ambient temperatures and reduces the distance that the molten solder must travel before application to a contact of an electronic component.

### BACKGROUND

1. Technical Field

The present disclosure relates to soldering apparatuses, and particularly to a multi-spot soldering apparatus.

2. Description of Related Art

FIG. 1 shows a multi-spot soldering apparatus 1 in a prior art. The multi-spot soldering apparatus 1 is usually placed on a solder pot 3 for soldering a number of elements 20 mounted on a printed circuit board (PCB) 2. The multi-spot soldering apparatus 1 includes a bottom plate 11 and a number of protrusions 10 mounted on the bottom plate 11. Each protrusion 10 defines an opening 101 passing through the protrusion 10 and the bottom plate 11. Height of each protrusion 10 is approximately 20 mm, thereby avoiding burning to the user when taking the PCB 2 which has been soldered away from the protrusion 10. When soldering the PCB 2, the multi-spot soldering apparatus 1 is placed on the solder pot 3, each element 20 on the PCB 2 is aligned on each protrusion 1. Power is applied to the solder pot 3 to deliver molten solder material to pass through the opening 101 to perform a wave soldering operation on the PCB 2 at a temperature of approximately 260 degrees Celsius. However, due to the height of the protrusion 10 and a width of the opening 101, the temperature of the solder material from the solder pot 3 falls, which prevents a preheating temperature for the elements 20 on the PCB 2 being reached, and causes bad soldering results for the number of elements 20 on the PCB 2.

Therefore, what is needed is a multi-spot soldering apparatus to overcome the described limitations.

### BRIEF DESCRIPTION OF THE DRAWINGS

FIG. 1 shows a multi-spot soldering apparatus in a prior art.

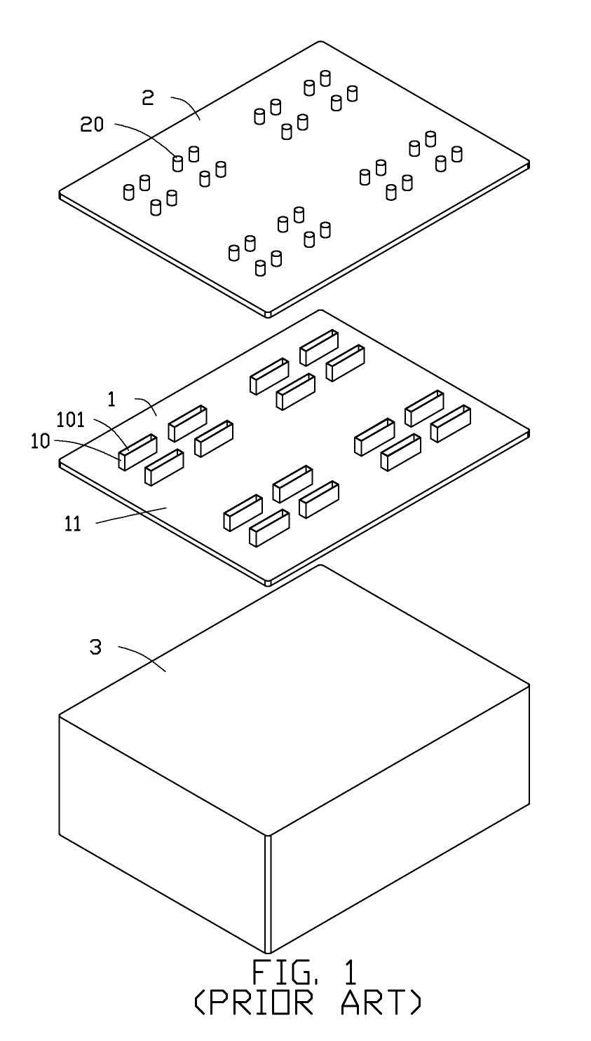

FIG. 2 shows a multi-spot soldering apparatus in accordance with an exemplary embodiment.

### DETAILED DESCRIPTION

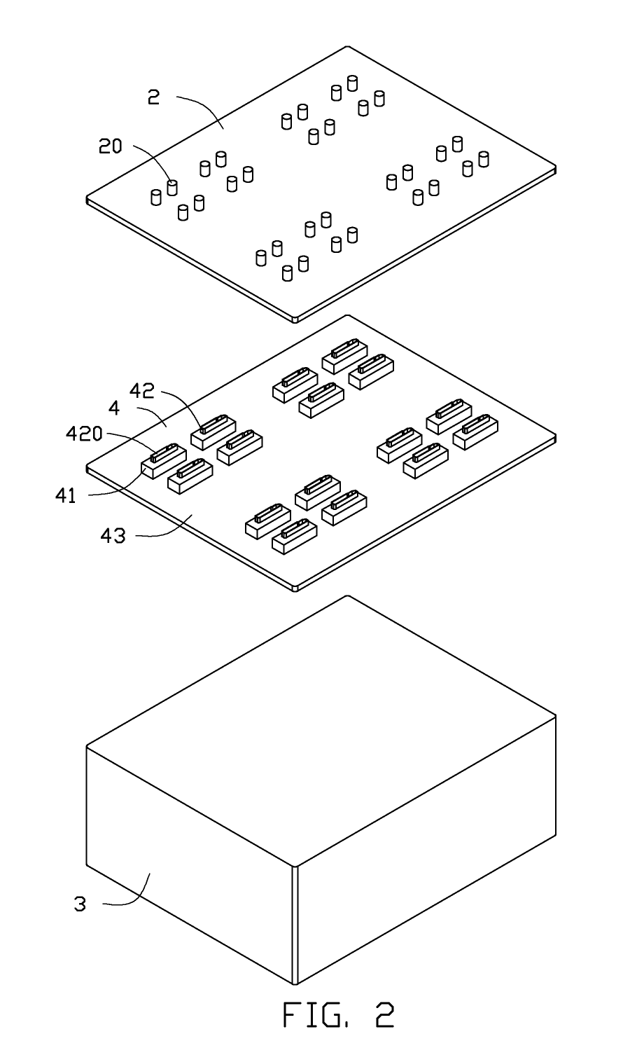

FIG. 2 shows a multi-spot soldering apparatus 4 (hereinafter “soldering apparatus”). The soldering apparatus 4 is placed on a solder pot 3, and is used to solder a number of elements 20 mounted on a printed circuit board (PCB) 2. The soldering apparatus 4 includes a bottom plate 43, a number of containers 41 mounted on the bottom plate 43 and communicating with the solder pot 3, and a number of protrusions 42 mounted on the number of the containers 41. Each protrusion 42 defines an opening 421 communicating with a container 41. The size of the container 41 is greater than the size of the protrusion 42. In one embodiment, the size of the container 41 is two times larger than the size of the protrusion 42. The sum of the height of the container 41 and the height of the protrusion 42 is not less than 20 mm, thereby avoiding burning to the user when taking away the PCB 2 which has been soldered.

In one embodiment, the amount of the containers 41 and the distribution structure of the containers 41 on the bottom plate 43 are related to the amount of the elements 20 and the distribution structure of the elements 20 on the PCB 2. The bottom plate 43 is made of stainless material, such as titanium alloy.

When soldering the elements 20 on the PCB 2 by the soldering apparatus 4, the soldering apparatus 4 is placed on the solder pot 3, a first power is applied to the solder pot 3 to continuously deliver the solder material to perform a wave soldering operation on the container 41, thereby storing a predetermined amount of the solder material in the container 41. Therein, the moving distance of the solder material from the solder pot 3 to the container 41 is equal to the height of the container 41. After the container 41 has stored the solder material, the PCB 2 is placed on the soldering apparatus 4, and each element 20 corresponds to an opening 421 of the protrusion 42. Then a second power exceeding the first power is applied to the solder pot 3 to deliver the solder material stored in the container 41 to pass through the opening 421 to perform a wave soldering operation on elements 20 of the PCB 2. That is, the moving distance for the soldering material from the container 41 to the elements 20 is equal to the height of the protrusion 42.

During the process of soldering the elements 20, because the container 41 has stored the predetermined amount of solder material, the size of the container 41 is more than the size of the protrusion 42, and the sum of the of the height of the container 41 and the height of the protrusion 42 is approximately 20 mm, the moving distance for the soldering material from the container 41 to the elements 20 is thus equal to the height of the protrusion 42. This height is less than 20 mm, significantly lower than the corresponding height in prior art, thereby avoiding the bad soldering results, which is caused by the amount of the solder material. Furthermore, because the moving distance of the soldering material from the container 41 to the elements 20 is reduced, the preheating temperature for the elements 20 on the PCB 2 can be reached more quickly and more efficiently, thereby avoiding the bad soldering results.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A multi-spot soldering apparatus for being placed on a solder pot, and configured to weld a plurality of elements mounted on a printed circuit board (PCB), the multi-spot soldering apparatus comprising:
a bottom plate to be placed on the solder pot;
a plurality of containers mounted on the bottom plate and to communicate with the solder pot; and
a plurality of protrusions mounted on the containers, and each of the protrusions defining an opening communicating with a corresponding container; wherein the size of each of the plurality of containers is greater than the size of each of the plurality of protrusions.

2. The multi-spot soldering apparatus as described in claim 1, wherein height of the container is two times higher than the height of the protrusion.

3. The multi-spot soldering apparatus as described in claim 1, wherein the size of the container is two times larger than the size of the protrusion.

4. The multi-spot soldering apparatus as described in claim 1, wherein the sum of the height of the container and the height of the protrusion is not less than 20 mm.

5. The multi-spot soldering apparatus as described in claim 1, wherein an amount of the plurality of containers and a distribution structure of the plurality of containers on the bottom plate are related to an amount of elements on the PCB and a distribution structure of the elements on the PCB.

6. The multiple-spot soldering apparatus as described in claim 1, wherein the bottom plate is made of stainless material.
